(19) United States
(12) Patent Application Publication
(10) Pub. No.: US 2010/0203682 A1
(43) Pub. Date: Aug. 12, 2010

(54) SEMICONDUCTOR DEVICE AND METHOD FOR MANUFACTURING SAME

(75) Inventors: Hideaki Kikuchi, Kawasaki (JP); Kouichi Nagai, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Yokohama-shi (JP)

(21) Appl. No.: 12/763,729

(22) Filed: Apr. 20, 2010

Related U.S. Application Data
(62) Division of application No. 11/902,244, filed on Sep. 20, 2007.
Application No. 11/902,244 is a continuation of application No. PCT/JP2005/005263, filed on Mar. 23, 2005.

(51) Int. Cl. H01L 21/60; H01L 21/56

(52) U.S. Cl. 438/123; 438/124; 257/E21.504; 257/E21.509

(57) ABSTRACT

A semiconductor device including a semiconductor device, an integrated circuit chip, a sealing resin encapsulating the integrated circuit chip and an insulating waterproof film covering at least a portion of a surface of said sealing resin and preventing penetration of moisture into the sealing resin.

### CROSS-REFERENCE TO RELATED APPLICATIONS

This application is a division of U.S. application Ser. No. 11/902,244, filed on Sep. 20, 2007, which is a continuation of International Application No. PCT/JP2005/005263 filed on Mar. 23, 2005.

### TECHNICAL FIELD

The embodiments discussed herein are directed to a semiconductor device suitable for piezoelectric devices and the method manufacturing the same.

### BACKGROUND ART

As a package structure of a semiconductor device including a lead frame, a Quad Flat Package (QFP), a Small Outline Package (SOP), a Thin Small Outline Package (TSOP), and so on can be cited. In recent years, miniaturization and the reduction in thickness of packages have been developed mainly for the IC packages used for portable devices and the like, and the demands for shifting from the packages such as the QFP, the SOP or the like to the TSOP, which is a thin film package, have been growing. FIG. 9 is a partial cutaway view showing a conventional semiconductor device having a SOP structure, and FIG. 10 is a partial cutaway view showing a conventional semiconductor device having a TSOP structure.

As shown in FIG. 9 and FIG. 10, in a conventional semiconductor device having the SOP structure or having the TSOP structure, an integrated circuit chip (IC chip) 105 is mounted on a die pad 104, and electrodes provided in the IC chip 105 and leads 108, which are external terminals, are connected via bonding wires 106. The IC chip 105, the bonding wires 106 and so on are encapsulated with a sealing resin 107.

Then, as shown in FIG. 6, the conventional semiconductor device 103 having the TSOP structure composed as described above is mounted above a printed circuit board 101 on which a Cu pad 102 is provided. The semiconductor device having the SOP structure is mounted in the same way as above.

In a conventional semiconductor device composed in this way, packaging prevents penetration of moisture or the like from outside.

However, as reduction in thickness of semiconductor devices advances, there is a growing tendency of malfunction and deterioration of characteristics.

Patent Document 1: Japanese Patent Application Laid-open No. Hei 10-326992

Patent Document 2: Japanese Patent Application Laid-open No. 2002-359257

### SUMMARY

It is an aspect of the embodiments discussed herein to provide a semiconductor device including a semiconductor device, an integrated circuit chip, a sealing resin encapsulating the integrated circuit chip and an insulating waterproof film covering at least a portion of a surface of the sealing resin and preventing penetration of moisture into the sealing resin.

### BRIEF DESCRIPTION OF THE DRAWINGS

FIG. 1 is a cross sectional view showing a semiconductor device according to a first embodiment;

FIG. 2 is a cross according view showing a semiconductor device according to a second embodiment;

FIG. 3 is a cross sectional view showing a semiconductor device according to a third embodiment;

FIG. 4 is a cross sectional view showing a semiconductor device according to a fourth embodiment;

FIG. 5 is a cross sectional view showing a semiconductor device according to a fifth embodiment;

FIG. 6 is a cross sectional view showing a conventional semiconductor device;

FIG. 7 is a cross sectional view showing penetration of moisture into a sealing resin 107 and an IC chip 105;

FIG. 8 is a cross sectional view showing compression stress working on an IC chip 105;

FIG. 9 is a partial cutaway view showing a conventional semiconductor device having a SOP structure;

FIG. 10 is a partial cutaway view showing a conventional semiconductor device having a TSOP structure;

FIG. 11A is a cross sectional view showing an example of a stacked type (2 chips) stack MCP;

FIG. 11B is a cross sectional view showing an example of a stacked type (3 chips) stack MCP;

FIG. 11C is a cross sectional view showing another example of a stacked type (2 chips) stack MCP;

FIG. 11D is a cross sectional view showing another example of a stacked type (3 chips) stack MCP;

FIG. 12A is a cross sectional view showing an example of a double-sided (2 chips) FBGA;

FIG. 12B is a cross sectional view showing an example of a double-sided (3 chips) FBGA;

FIG. 12C is a cross sectional view showing another example of a double-sided (3 chips) FBGA;

FIG. 13A is a cross sectional view showing an example of a side-to-side type (2 chips) plane MCP;

FIG. 13B is a cross sectional view showing an example of a side-to-side type (3 chips) plane MCP;

FIG. 14 is a cross sectional view showing an example of a three dimensional package module; and

FIG. 15 is a view showing various packages.

### DETAILED DESCRIPTION OF THE PREFERRED EMBODIMENTS

Upon pursuing the cause of the above-described disadvantage of the related art, the present inventors have found the following phenomena.

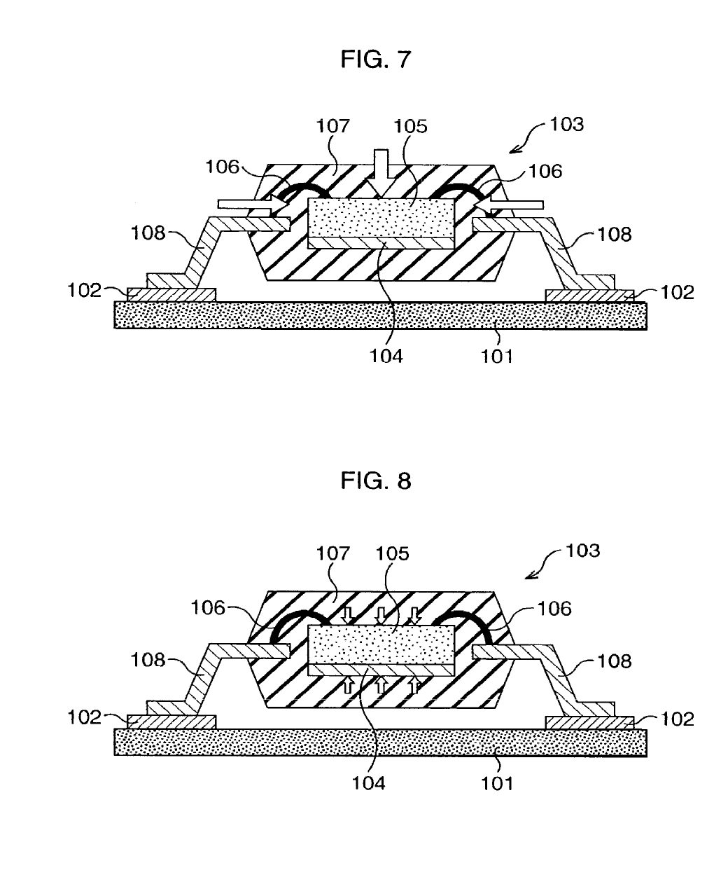

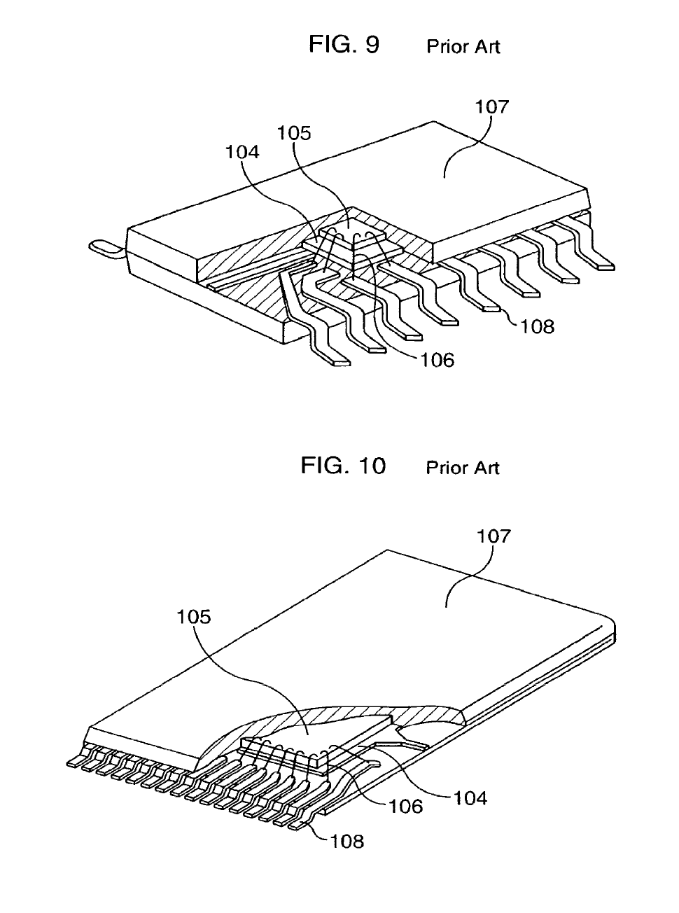

Since the TSOP structure is a thin type, a resin of low viscosity is used as a sealing resin 107. Generally, the filler content of a low viscosity resin is rather low, and the hygroscopicity of such a resin is high. Therefore, especially in a semiconductor device 103 having the TSOP structure, as shown in FIG. 7, moisture may penetrate into the sealing resin 107. Once moisture enters into the sealing resin 107, the resin 107 itself often expands or deforms. As a result, a compression stress works on an IC chip 105 as shown in FIG. 8. When the IC chip 105 includes a piezoelectric device such as a ferroelectric capacitor composing a ferroelectric memory, the compression stress may act on the piezoelectric device, which causes it malfunctions. For example, a data storage function of the ferroelectric memory may be damaged, or data readout may become unable.

In the TSOP structure, the length of a lead 108 is shorter than that of the SOP structure. Accordingly, the distance between an end of the lead 108 and the IC chip 105 become short, and moisture in the air may sometimes reach the IC chip 105 via the lead 108, as shown in FIG. 7. As a result, when the ferroelectric memory is included in the IC chip 105, the characteristic of the ferroelectric capacitor is deteriorated owing to reduction by hydrogen in moisture, or the like.

Furthermore, when pin holes or cracks occur in the sealing resin 107 due to moisture absorption or the like, the amount of transmission of ultraviolet beams increases, and the characteristics of semiconductor device such as the ferroelectric capacitor or the like may sometimes deteriorate due to the influence of ultraviolet rays. The deterioration of the characteristics accompanying the transmission of ultraviolet rays may occur when the sealing resin 107 is thin as in the case of the TSOP structure.

Considering such disadvantages, the present inventors have come up with various forms of the embodiments shown below.

Hereinafter, the embodiments will be explained concretely with reference to the attached drawings.

### First Embodiment

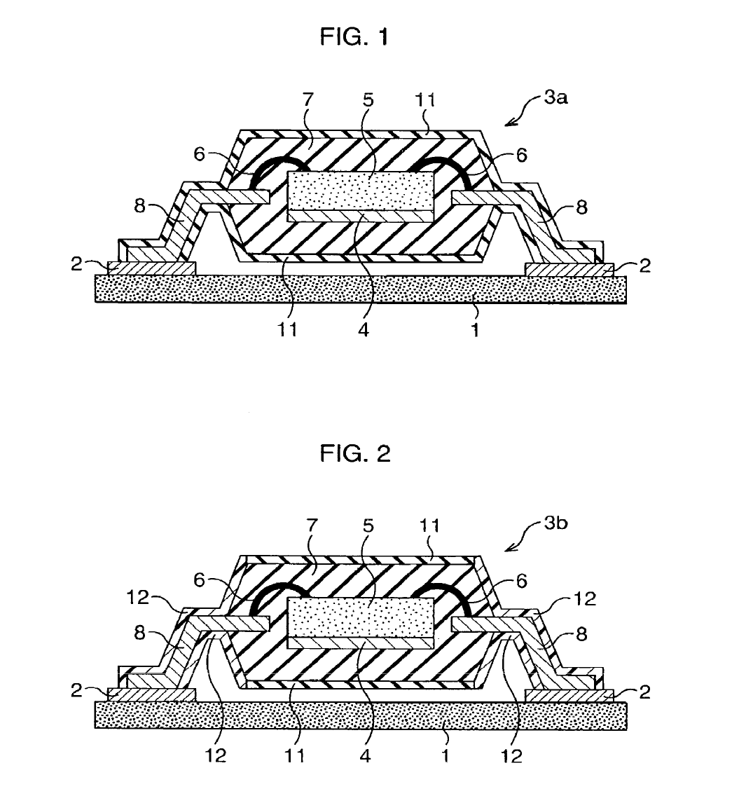

First, a first embodiment will be explained. FIG. 1 is a cross sectional view showing a semiconductor device according to the first embodiment.

In the first embodiment, an integrated circuit chip (IC chip) 5 is mounted on a die pad 4, and electrodes provided on the IC chip 5 and leads 8, which are external terminals, are connected via bonding wires 6. The IC chip 5, the bonding wires 6 and so on are encapsulated with a sealing resin 7, so that a package of a TSOP structure is constructed. Further, in the present embodiment, the sealing resin 7 and the leads 8 are covered with an alumina film 11 serving as a waterproof film. The thickness of the alumina film 11 is designed to be 20 nm or more, preferably about 100 nm to about 200 nm. The blocking effect against moisture and hydrogen is higher as the thickness of the alumina film 11 increases. When the thickness is less than 20 nm, there is a possibility of an insufficient blocking effect.

A semiconductor device 3a thus structured is mounted on a printed circuit board 1 on which Cu pads 2 are provided. When the whole surface of the lead 8 is covered with the alumina film 11, removal of the alumina film 11 is required at the contact position with the Cu pad 2.

According to such a first embodiment, since the sealing resin 7 is covered with the alumina film 11, penetration of moisture can be prevented even when highly hygroscopic resin is used for the sealing resin 7. Therefore, deformation accompanying moisture absorption, and the effect of the compression stress can be prevented. Accordingly, it is possible to suppress malfunctions caused by the effect of the stress even when a piezoelectric device is included in the IC chip 5. Furthermore, since the most part of the lead 8, and the vicinity of the interface between the lead 8 and the sealing resin 7 are covered with the alumina film 11, the penetration of moisture into the IC chip 5 via the lead 8 can be prevented. Accordingly, even when a ferroelectric memory is included in the IC chip 5, deterioration of the characteristics in a ferroelectric capacitor can be suppressed.

When a ferroelectric memory is provided in the IC chip 5, it is preferable to use a resin having the filler content of 80 vol % or more for the sealing resin 7 to be used for a package in a TSOP typed structure as in the first embodiment. When it is used for a package in the SOP typed structure, the filler content of the sealing resin is preferably 90 vol % or more. The reason the preferable filler content differs according to the package structure is that the sealing resin for the TSOP package is thinner than the SOP type, and that much lower hygroscopicity is required.

Furthermore, it is preferable to use spherical fillers for the fillers, irrespective of the type of package structure. This is because when spherical fillers are used, the surface of the sealing resin gives relatively favorable smoothness, and coverage of a waterproof film becomes high.

A method for manufacturing the semiconductor device according to the first embodiment will be explained here. First, a silver paste is applied on the die pad 4 of a lead frame, and then, the IC chip 5 is mounted thereon. Next, the silver paste is cured for two hours at 155° C., for example. Then, the bonding wires 6 are bonded conducted for 10 seconds at 240° C. or lower, for example. Thereafter, the sealing resin 7 is filled for 60 seconds at 175° C., for example. Then, the sealing resin 7 is cured for 4 hours at 170° C., for example, and plating is performed to the lead frame. Thereafter, the alumina film 11 serving as a waterproof film is formed, a model number or the like is stamped on the upper surface of the sealing resin 7, and the lead frame is cut and bended.

It is preferable to form the alumina film 11 after the sealing resin 7 is completely dried. This is because if moisture remains in the sealing resin 7, the moisture remained inside is apt to diffuse due to temperature increase at the time of later reflowing (mounting on the printed circuit board 1) or the like, which causes deterioration of the characteristics of a device in the IC chip 5, such as a ferroelectric capacitor. In addition, from the same reason, it is preferable to form the alumina film 11 within four hours after completion of curing of the sealing resin 7. In other words, since moisture is included in the air, there is a possibility that moisture is absorbed in the sealing resin 7 if it is left as is for more than four hours. Even in this case, it is preferable to form a waterproof film such as an alumina film or the like after plating process.

As a waterproof film to prevent penetration of moisture, a metal oxide film such as a titanium oxide film or the like, a metal nitride film such as silicon (Si) nitride film, an aluminum (Al) nitride film, a boron (B) nitride film, a titanium aluminum nitride (TiAlN) film, or the like, a carbide film such as a silicon carbide film or the like, and a carbon film such as a diamond-like carbon film or the like can be used instead of the alumina film 11.

As a method for forming these waterproof films, such as a sputtering method and a CVD method can be cited. It should be noted that, when the ferroelectric capacitor is provided in the IC chip 5, a desirable temperature for forming the waterproof film is 240° C. or lower so as to avoid deterioration due to heat. From the similar reason, a desirable bonding temperature of the bonding wire 6 is 240° C. or lower. When the waterproof film is formed by a sputtering method, it is possible to form a film having a uniform thickness as a whole by rotating (rotation on its axis) the IC chip 5, the sealing resin 7, and so on. Further, when a waterproof film is formed only on a portion of the semiconductor device 3a irrespective of type in method for manufacturing, it is possible to form a waterproof film only on a necessary portion by previously covering a portion where the formation of a waterproof film is unnecessary.

### Second Embodiment

A second embodiment will be explained. FIG. 2 is a cross sectional view showing a semiconductor device according to the second embodiment.

In the second embodiment, the alumina film 11 covers only the upper and the bottom surfaces of the sealing resin 7. In the present embodiment, a water repellent resin film 12 that covers the side surfaces of the sealing resin 7 and the lead 8 is formed as another waterproof film. When a semiconductor device 3b thus configured is mounted on the printed circuit board 1, it is necessary to remove the water repellent resin film 12 at the contact position with the Cu pad 2.

In such a second embodiment, the penetration of moisture into the IC chip 5 via the lead 8 can be prevented by the water repellent resin film 12. Accordingly, an effect similar to that of the first embodiment can be obtained.

It should be noted that as the water repellent resin film 12, for example, a fluorine base resin film, silicone base resin film, or the like can be used. The water repellent resin film 12 may be formed by jetting with a spray, or may be formed by stacking like laminating. In the case of conducting a jet using a spray, when a waterproof film is formed only on a portion of the semiconductor device 3b similarly to the case of the first embodiment, it is possible to form the water repellent resin film 12 for a required portion only by previously covering the position where the formation is not required.

### Third Embodiment

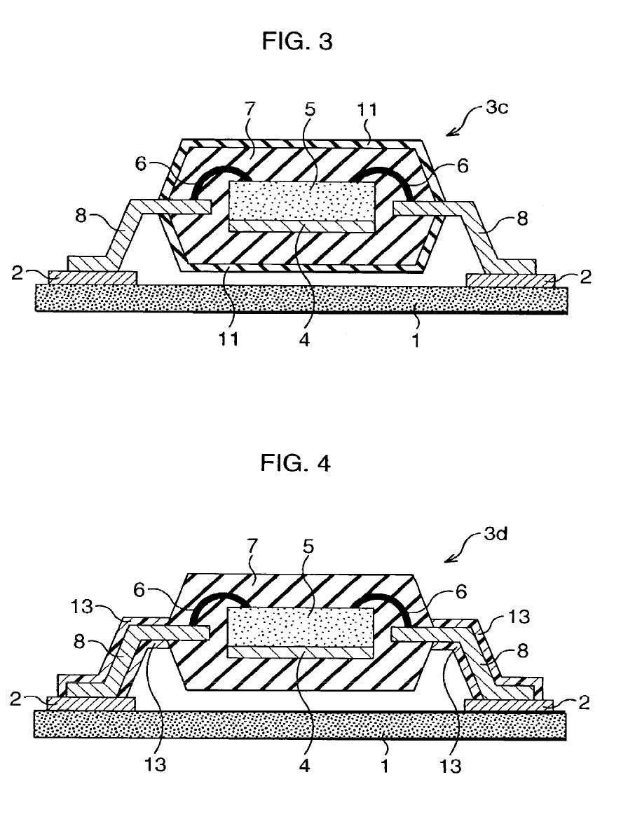

Next, a third embodiment will be explained. FIG. 3 is a cross sectional view showing a semiconductor device according to the third embodiment.

In the third embodiment, the alumina film covers only the sealing resin 7. In the semiconductor device 3c according to the third embodiment, although resistance to penetration of moisture via the lead 8 is lower than that of the first embodiment, it can prevent a malfunction due to moisture absorption of the sealing resin 7. Note that a waterproof film made using other materials such as a water-repellent resin or the like may be formed instead of the alumina film 11.

### Fourth Embodiment

Next, a fourth embodiment will be explained. FIG. 4 is a cross sectional view showing a semiconductor device according to the fourth embodiment.

In the fourth embodiment, a water repellent resin film 13 covering the leads 8 is formed with a spray or the like. In the semiconductor device 3d according to the fourth embodiment, although resistance to moisture penetration of the sealing resin 7 is lower than that of the first embodiment, it can be prevent deterioration of the characteristics caused by the penetration of moisture via the leads 8. Note that it a waterproof film made using other materials such as a water-repellent resin or the like may be formed instead of the alumina film 13. Besides, it should be noted that the water repellent resin film 13 may cover a part of the sealing resin 7 so as to suppress moisture penetration from a gap between the leads 8 and the sealing resin 7.

### Fifth Embodiment

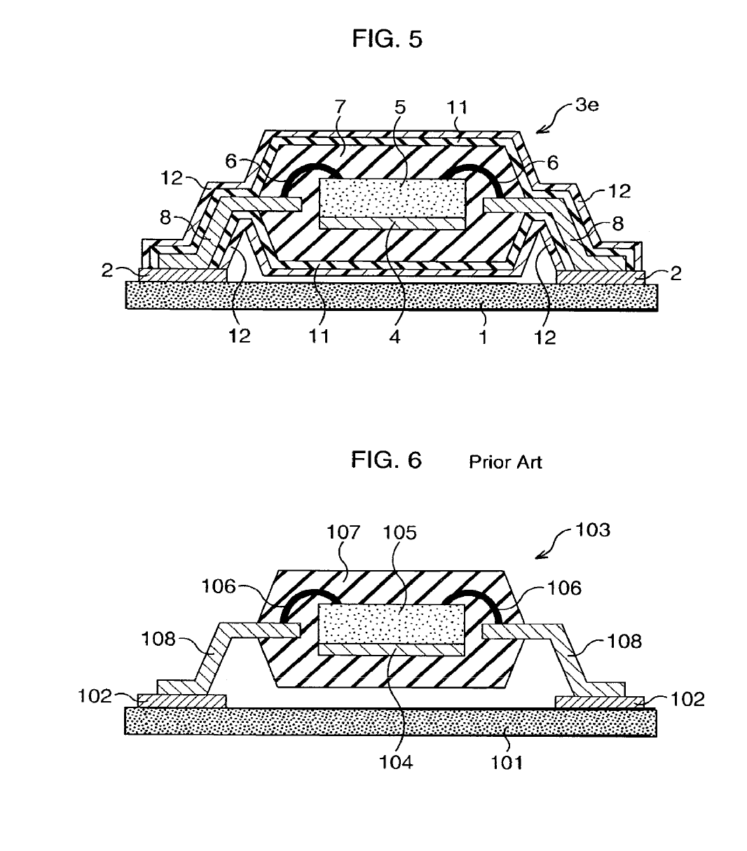

Next, a fifth embodiment will be explained. FIG. 5 is a cross sectional view showing a semiconductor device according to the fifth embodiment.

In the fifth embodiment, the alumina film 11 is formed similarly to the first embodiment, and the water repellent resin film 12 is further formed to cover the alumina film 11. By the semiconductor device 3e according to the fifth embodiment, it is possible to ensure further higher water resistance.

It should be noted that, in the first to the fifth embodiments, the waterproof film is formed as a film to cover the sealing resin 7, and it is preferable that an ultraviolet ray blocking film that blocks ultraviolet rays incident into the sealing resin 7 if further formed. For such an ultraviolet ray blocking film, either a film to absorb ultraviolet rays or to reflect the ultraviolet rays can be used. As a preferable film to absorb ultraviolet rays, a film made of a material having the energy gap of about 3.1 eV is desirable, and a titanium (Ti) oxide film is an example for such a film.

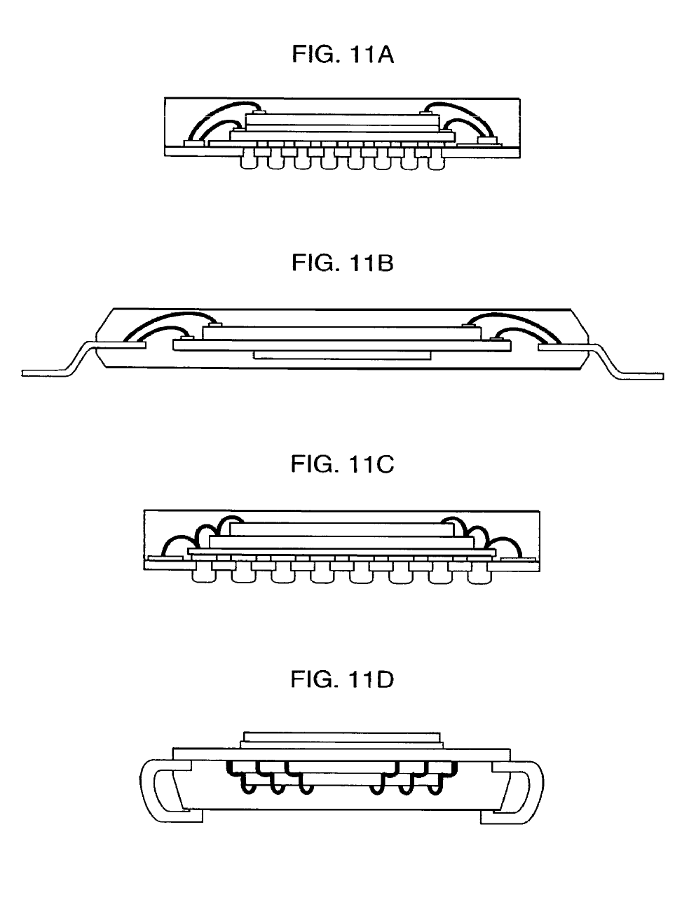

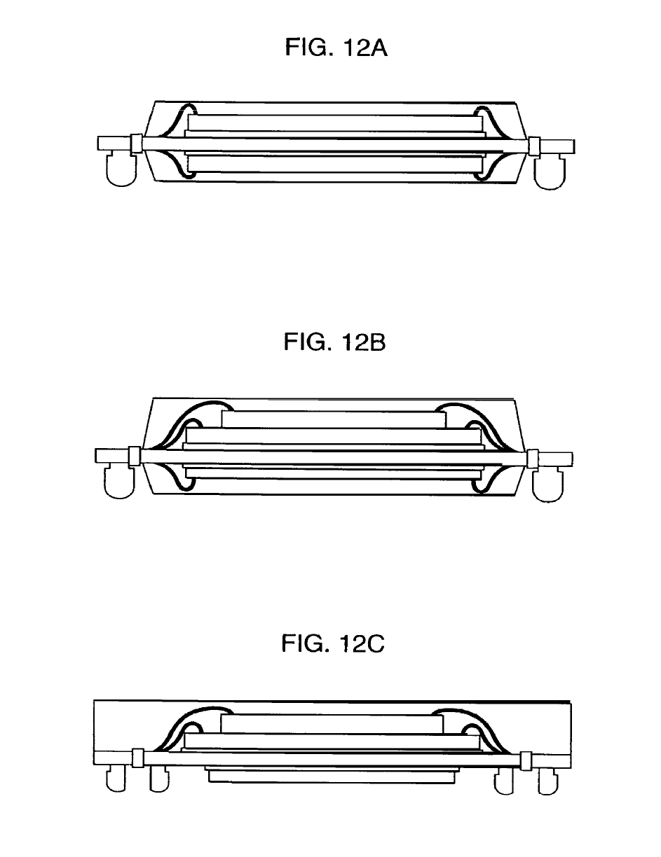

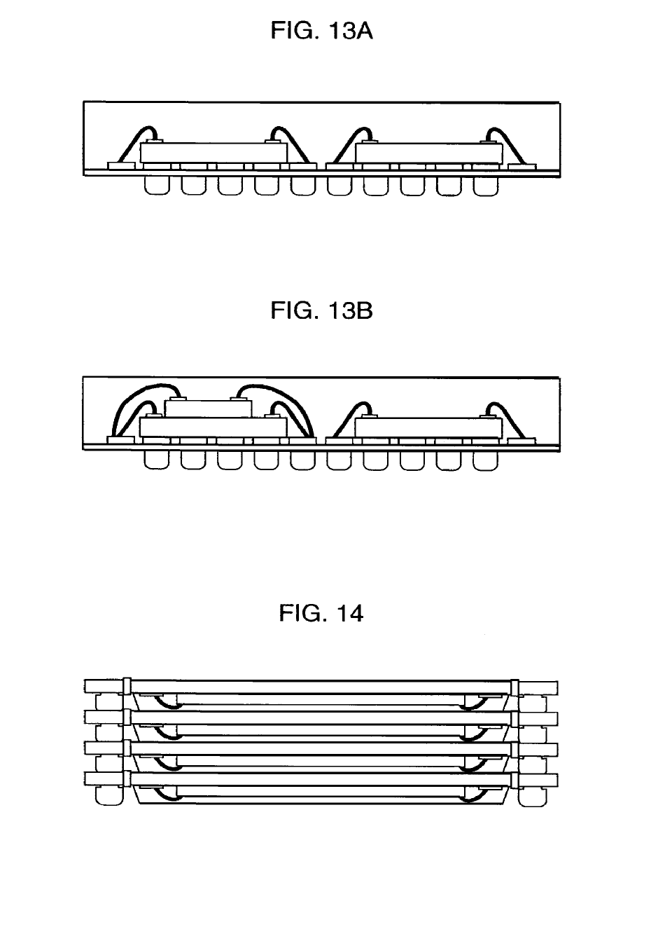

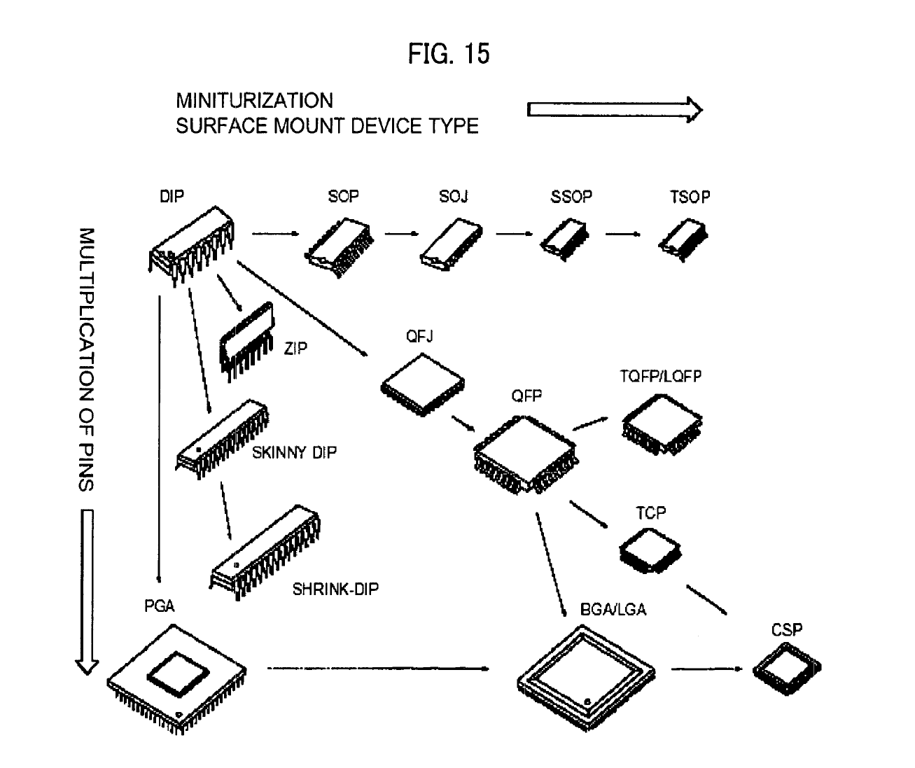

In addition to these packages, it is also possible to apply the embodiment to a package without a lead frame. For instance, the embodiment can be applied to a stacking type stack Multi Chip Package (MCP) shown in FIG. 11A to FIG. 11D, a double sided type Fine Pitch Ball Grid Array (FBGA) shown in FIG. 12A to FIG. 12C, a side-to-side type plane MCP shown in FIG. 13A to FIG. 13B, a three dimensional package module shown in FIG. 14, or the like. It is also possible to apply the embodiment to a Dual Inline Package (DIP), a Skinny Dual Inline Package (SKINNY DIP), a Shrink Dual Inline Package (SHRINK DIP), a Zigzag Inline Package (ZIP), a Pin Grid Array (PGA), a Small Outline L-Leaded Package (SOP), a Small Outline J-Leaded Package (SOJ), a Shrink Small Outline L-Leaded Package (SSOP), a Thin Small Outline L-Leaded Package (TSOP), a Quad Flat J-Leaded Package (QFJ), a Quad Flat L-Leaded Package (QFP), a Thin Quad Flat L-leaded Package/Low Profile Quad Flat L-Leaded Package (TQFP/LQFP), a Ball Grid Array/Fine Pitch Land Grid Array (BGA/LGA), a Tape Carrier Package (TCP), a Wafer Level Chip Size Package (CSP), etc.

It should be noted that Patent Document 1 discloses a metal film for blocking an electromagnetic wave noise around a sealing resin. When the metal film is formed around the sealing resin, however, it must be quite carefully constructed so that the metal film does not come into contact with the lead frame, otherwise short circuit might occur.

In addition, in Patent Document 2, it is disclosed that a gate electrode or the like is covered with a polyimide film and a metal film for the purpose of improving hygroscopicity. When this technology is applied to the package so as to cover the sealing resin with a metal film, it causes the same problem as that which occurred in Patent Document 1.

The order of embodiments does not have a particular meaning and has nothing to do with the importance of the embodiments.

### INDUSTRIAL APPLICABILITY

As described above, according to the embodiment, it is possible to ensure high water resistance even when a sealing resin having relatively high hygroscopicity. Accordingly, it is possible to suppress malfunctions of an integrated circuit chip and the concomitant deterioration of characteristics accompanying penetration of moisture.

What is claimed is:

1. A method for manufacturing a semiconductor device comprising:
fixing an integrated circuit chip over a die pad of a lead frame;
encapsulating said integrated circuit chip with a sealing resin; and
forming an insulating waterproof film covering at least a portion of a surface of said sealing resin and preventing penetration of moisture into said sealing resin,
wherein an integrated circuit chip containing a ferroelectric memory is used as said integrated circuit chip, and
wherein said insulating waterproof film is formed at 240° C. or lower.

2. The method for manufacturing the semiconductor device according to claim 1, wherein at least one kind of film selected from a group consisting of a metal oxide film and a metal nitride film is formed as said insulating waterproof film.

3. The method for manufacturing a semiconductor device according to claim 1, wherein the water proof film is formed by one of a sputtering method and a CVD method.

4. The method for manufacturing a semiconductor device according to claim 3, further comprising bonding a bonding wire at 240° C. or lower, between said fixing said integrated circuit chip and said step of encapsulating said integrated circuit chip with said sealing resin.

5. The method for manufacturing a semiconductor device according to claim 1,
wherein said encapsulating said integrated circuit chip with said sealing resin includes curing said sealing resin, and
wherein said forming said insulating waterproof film is started within four hours after completion of said curing said sealing resin.
